(19) United States
(12) Patent Application Publication
(10) Pub. No.: US 2021/0021072 A1
(43) Pub. Date: Jan. 21, 2021

(54) Spring Pin-Based Electrical Interconnect System

(71) Applicant: Paricon Technologies Corporation, Taunton, MA (US)

(72) Inventor: Larre H. Nelson, Attleboro, MA (US)

(21) Appl. No.: 16/933,365

(22) Filed: Jul. 20, 2020

Related U.S. Application Data
(60) Provisional application No. 62/876,626, filed on Jul. 20, 2019.

(51) Int. Cl. H01R 13/24; H01R 12/71; G01R 1/067; G01R 1/04; G01R 31/28

(52) U.S. Cl. CPC H01R 13/2414; H01R 12/714; H01R 13/2471; G01R 1/06722; H01R 2201/20; G01R 31/2886; H01R 13/2485; H01R 13/2421; G01R 1/0466

(57) ABSTRACT

A spring pin-based electrical interconnect system with a non-conductive socket body, a spring pin located in part in the socket body and defining two ends, an anisotropically-conductive elastomeric sheet with first and second opposed surfaces wherein the first surface is in contact with a first end of the spring pin. A PCB is in contact with the second surface of the elastomeric sheet.

### CROSS-REFERENCE TO RELATED APPLICATION

This application claims priority of Provisional Application 62/876,626 filed on Jul. 20, 2019.

### BACKGROUND

This disclosure relates to an electrical interconnect system.

Spring pins used for electrical connectivity are very durable and dependable. When used in an IC test socket, they are usually 5 mm-8 mm long and have a bandwidth of about 10 GHz. Spring pins of this length have good spring forces without too much stress on the spring material. Also there is enough room inside the barrel cavity to get plenty of plunger travel, enough room to allow both plungers to travel, and enough room to employ special methods to minimize contact resistance.

In order to get a higher bandwidth with a spring pin, the pin has to be shorter. Typically, when a spring pin length is reduced to about 3 mm, the bandwidth is increased to about 20 GHz but some of the other specifications might suffer. For example: the spring force might be reduced, or the plunger travel might be limited.

If the spring pin length can be reduced to about 1.5 mm, the bandwidth can increase to about 30 GHz. At this length, there are mechanical and manufacturing challenges that are difficult to overcome. Due to the materials used on the spring pins and the very tiny size of the component parts, these spring pins are relatively expensive to manufacture.

Most test probes make a contact to the device under test (DUT) with the top plunger. The shape of the plunger tip and the material used in the plunger are unique to each test application. The center barrel of the test probe is used to hold the test probe in an insulating body and contains the plungers and the compression spring.

The bottom plunger is used to make a contact to a gold-plated PCB pad on the tester. The shape of the bottom plunger tip is usually spherical or conical to apply the maximum amount of pressure in a manner that does not damage the pad. The bottom plungers are usually machined from solid bars of brass, BeCu or steel, and plated with gold.

An improved test probe design places the compression spring on the OD of the test probe and feeds the top plunger shank into a cavity in the bottom plunger. The increased diameter of the compression spring on the OD of the test probe allows forces to be higher (with lower stress levels), allows for a large amount of plunger travel, and still keeps overall length of the test probe as short as possible.

Feeding the bottom shank of the top plunger into a hollow cavity in the bottom plunger also aids in keeping the test probe rigid and prevents wiggling of the top plunger from side to side.

But, if the hollow cavity of the bottom plunger is not plated well, this concept will result in poor contact resistance—since the two sliding parts of the test probe need a high quality noble metal surface. To improve plating quality, a side hole is typically drilled into the hollow cavity to provide a pressure release for captured gasses during plating and to facilitate the flow of the plating solutions into the cavity. These holes (called bleed holes) are expensive to manufacture and hard to do in a quality manner, because it is difficult to control the residual burrs from the drilling steps. Typically, the cavity drilling and the bleed hole drilling operations need to be repeated multiple times to remove the burrs.

### SUMMARY

The disclosure provides a way to get very short spring pins (uncompressed length between about 1.5 mm and 5-8 mm) while at the same time minimizing performance compromises and manufacturing costs.

Featured in this disclosure is a bleed hole at the bottom tip of the bottom plunger. This location for the bleed hole is easier to machine than a side hole, and still facilitates the plating process. The hole could potentially damage the PCB pad if there are residual burrs at the bottom of the plunger. Providing a slight chamfer to the entry location of the blind hole minimizes the risk of a burr. The resulting shape of the contact surface at the bottom of the plunger looks like a volcano rim, with an annular contact surface. A volcano rim is less damaging to the PCB pad than a sharp spherical tip, and will still provide a high-pressure geometry against the PCB pad to get a low resistance contact. A volcano rim shape is also more forgiving of alignment errors in the socket because a single contact geometry of a spherical tip might fall off the edge of the PCB pad, but a circular geometry will be more likely to hit a portion of the PCB pad when misaligned.

All examples and features mentioned below can be combined in any technically possible way.

In one aspect, a spring pin-based electrical interconnect system includes a non-conductive socket body, a spring pin located in part in the socket body and defining two ends, an anisotropically-conductive elastomeric sheet with first and second opposed surfaces, wherein the first surface is in contact with a first end of the spring pin, and a PCB in contact with the second surface of the elastomeric sheet.

Some examples include one of the above and/or below features, or any combination thereof. In an example the spring pin comprises a top plunger and a bottom plunger and an exterior spring. In an example the socket body comprises a cavity in which the spring pin is at least in part located. In an example the top plunger and the bottom plunger each comprise a flange located in the socket body cavity. In an example the top plunger comprises a flange located in the socket body cavity, and the bottom plunger comprises a flange that sits on the elastomeric sheet. In an example the elastomeric sheet is configured to facilitate electrical connection between the spring pin and an electrical contact on the PCB.

In another aspect a spring pin includes a top plunger element defining an electrical contact at one end, and a plunger at an opposed end, a bottom barrel element that defines a cavity with an open top, wherein the plunger of the top plunger element is located and able to move up and down within the cavity, and a bottom tip with a through-hole that communicates with the cavity, and a spring located outside of the top and bottom elements, the spring configured to produce a force that moves the plunger of the top element up within the cavity.

Some examples include one of the above and/or below features, or any combination thereof. In an example the spring pin further comprises a chamfer in the bottom tip. In an example the bottom tip is conical. In an example the bottom tip has a flat bottom. In an example the through-hole is in the flat bottom. In an example the bottom of the tip is annular. In an example the bottom element is unitary. In an example the bottom of the tip is closed except for the through-hole. In an example the top plunger further defines a flange between the ends.

### BRIEF DESCRIPTION OF THE DRAWINGS

FIG. 1 illustrates a spring pin in its expanded and contracted positions.

FIG. 2 illustrates a spring pin in its expanded and contracted positions.

FIG. 3 is a cross-sectional view of a spring pin in its expanded and contracted positions.

FIG. 4A is a cross-sectional view and FIG. 4B is a perspective view of a bottom plunger for a spring pin.

FIGS. 5A and 5B exemplify the CRES and electrical characteristics, respectively, of a spring pin.

### DETAILED DESCRIPTION

The spring pin can include a top plunger element defining an electrical contact at one end, a plunger at an opposed end, and an optional flange between the ends. A bottom barrel element defines a cavity with an open top. The plunger of the top plunger element is located and able to move up and down within the cavity. The bottom element has a bottom tip with a through-hole that communicates with the cavity. There is a spring located outside of the top and bottom elements. The spring is configured to produce a force that moves the plunger of the top element up within the cavity.

The spring pin can have a chamfer in its bottom tip. The bottom tip may be conical. The bottom tip may have a flat bottom. The through-hole may be in the flat bottom. The bottom of the tip may be annular. The bottom element may be unitary, i.e., it is a single unitary piece. In an example the bottom element is machined from a solid rod. The bottom of the tip may be closed except for the through-hole.

The spring pin-based electrical interconnect system can use extremely short spring pins in order to achieve very high bandwidths, while still achieving substantial vertical compliance and using traditional spring-pin manufacturing techniques. A result is a high-performance interconnect that is inexpensive to manufacture and easy to assemble.

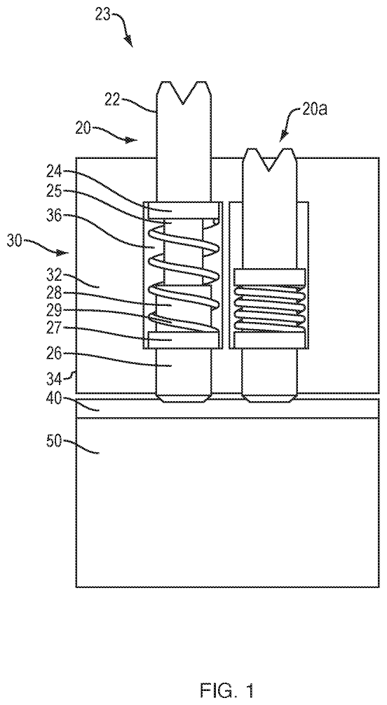

Several illustrative examples are shown in FIGS. 1-4. These examples are not limiting of the scope of the invention.

Spring pin-based electrical interconnect system 10, FIG. 1, includes spring pin 20 that is captured within non-conductive socket body 30. First spring pin end 23 is configured to connect to an electrical device such as a device under test. End 23 can have any desired shape/configuration of a type known in the field of spring pins. In an example the shape shown may be designed to contact a solder ball. Pin opposite (second) end 26 contacts anisotropically-conductive elastomeric sheet 40. Sheet 40 may be a sheet of Pariposer® material available from Paricon Technologies Corp., Taunton, Mass. USA. This material is disclosed in several patents, including U.S. Pat. Nos. 6,802,720, 8,834,986, and 6,854,985, each of which is incorporated herein by reference in its entirety and for all purposes. Spring pin 20 is made from three separate parts—top plunger 22, bottom plunger 26, and external spring 29. The parts can be made of any desired material, including heat-treated BeCu.

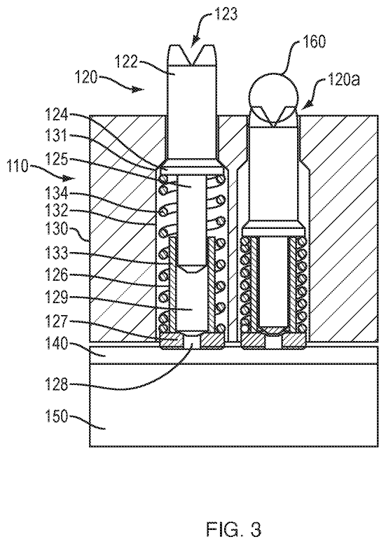

Spring pin 20 is held in cavity 36 of non-conductive socket body 30. In an example socket body 30 comprises halves 32 and 34 that are clamped or otherwise fixed or held together after the spring pin is placed into cavity 36. In this example, the pin is held in the cavity with flange 24 of top plunger 22 and flange 27 of bottom plunger 26 that both have a larger diameter than the smaller diameter of cavity 36. Lower shaft 25 of top plunger 22 fits within and is configured to move up and down within the hollow interior of upper shaft 28 of separate bottom plunger 26. This general arrangement is shown in the cross-sections of FIG. 3, described in more detail below. Bottom portion 34 of bottom plunger 26 sits on sheet 40. Sheet 40 sits on printed circuit board (PCB) 50. Spring-pin 20 is thus able to electrically connect an electrical device that is coupled to tip 23 to PCB 50. Spring pin 20 is depicted in its fully compressed state in illustration 20a.

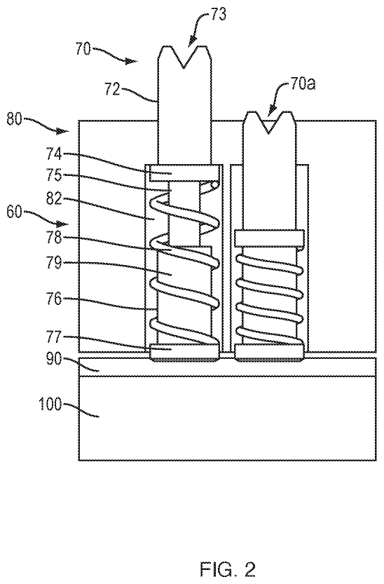

Spring pin-based electrical interconnect system 60, FIG. 2, includes spring pin 60 that is captured within non-conductive socket body 80. First spring pin end 73 is configured to connect to an electrical device such as a device under test. End 73 can have any desired shape/configuration of a type known in the field of spring pins. The shape shown may be designed to contact a solder ball. Opposite end (flange) 77 contacts anisotropically-conductive elastomeric sheet 90. Sheet 90 may be a sheet of Pariposer® material available from Paricon Technologies Corp., Taunton, Mass. USA, as described above. Spring pin 60 is made from three separate parts—top plunger 72, bottom plunger 76, and external spring 78. The parts can be made of any desired material, including heat-treated BeCu.

Spring pin 60 is held in cavity 82 of non-conductive socket body 80. In this example, this is accomplished with flange 74 of top plunger 72 that is larger than cavity 82, and sheet 90 against which lower flange 77 sits. Shaft 75 of top plunger 72 fits within and is configured to move up and down within the hollow interior of shaft 79 of bottom plunger 76. This general arrangement is shown in the cross-sections of FIG. 3. Sheet 90 sits on printed circuit board (PCB) 100. Spring-pin 70 is thus able to electrically connect an electrical device that is coupled to tip 73 to PCB 100. Spring pin 70 is depicted in its fully compressed state in illustration 70a.

Spring pin-based electrical interconnect system 120, FIG. 3, includes spring pin 120 that is captured within non-conductive socket body 130. Spring pin end 123 is configured to connect to an electrical device such as a device under test. End 123 can have any desired shape/configuration of a type known in the field of spring pins. The shape shown may be designed to contact a solder ball 160. Opposite end 127 contacts anisotropically-conductive elastomeric sheet 140. Sheet 140 may be a sheet of Pariposer® material available from Paricon Technologies Corp., Taunton, Mass. USA, described above. Spring pin 120 is made from three separate parts—top plunger 122, bottom plunger 126, and external spring 134. The parts can be made of any desired material, including heat-treated BeCu.

Spring pin 120 is held in cavity 132 of non-conductive socket body 130. In this example, this is accomplished with flange 124 of top plunger 122 held within cavity 132, and flange 127 of bottom plunger 126 that sits against sheet 140. Shaft 125 of top plunger 122 fits within and is configured to move up and down within the hollow interior 129 of shaft 133 of bottom plunger 126. In an example shaft 125 has an outside diameter that is approximately the same as the inside diameter of shaft or barrel 133, so that the two shafts make electrical contact and so are able to carry electrical signals through the spring pin. Sheet 140 sits on printed circuit board (PCB) 150. Spring-pin 120 is thus able to electrically connect an electrical device that is coupled to tip 123 to PCB 150. Spring pin 120 is depicted in its fully compressed state in illustration 120a.

In one non-limiting example, the spring pin exhibits a contact pitch of 0.4-1.0 mm, an uncompressed contact length of 3.13 mm, a contact travel of 0.4 mm, a contact resistance of less than 50 mΩ, a contact inductance of 0.8-1.5 nH, a bandwidth of up to 40 GHz, a current rating of up to 3 A, and a temperature rating of 150° C.

More generally, the top plunger may have a very traditional design and function. Since the plunger can be made on an automatic lathe, the traditional flexibility and the tip shape variation are retained. The flange midway along the plunger length acts as a retainer to keep the plunger in the socket block and as a platform for the compression spring to push against. The hollow bottom barrel/plunger is a hollow piece that accepts the bottom end of the top plunger. It is typically made of machined brass. In the version shown in FIG. 1, the purpose of the bottom flange is the same as the flange of the top plunger—retention in the socket body and a platform for the spring to push against. In the version shown in FIG. 2, the lower flange is only used as a platform for the spring, and the pin is retained by the Pariposer. Typically, the bottom end of the bottom barrel has an opening (e.g., opening 128, FIG. 3) that facilitates plating the ID of the bottom barrel. The spring is external of the plungers. Using an external spring, allows the current to flow through the core of the spring pin (minimizing contact resistance (CRES) and inductance). It also results in minimal stresses on the spring wire for a given spring force and travel. The spring may not need to have turned-in or flattened features on the last coils. This can create a bit of an off-pointing for the two plungers that has a biasing effect for the top plunger base sliding inside the bottom plunger ID. At the bottom of the spring pin, is a sheet of conductive elastomer. This sheet minimizes the wear of the open-ended brass barrel against the PCB test pad and the likelihood of pointing accuracy problems. In other versions (FIGS. 2 and 3), the Pariposer is also the means of retention to keep the pin in the socket body. Since the Pariposer elastomer has a universal grid of metal ball columns, there can be some amount of mis-alignment between the bottom of the spring pin and the PCB pad without creating an electrical open.

The spring pin components do not have to be assembled prior to loading in a socket body. The components can be made and shipped separately. They can all come together in the proper relationship to each other during the socket body assembly process. This as two advantages. It reduces the labor costs of the spring pins, and it allows for flexible replacement of only one component when something goes wrong in the socket (for example: a broken plunger tip). For spring pin 20 (FIG. 1), the assembly process is as follows: load the bottom barrel and the spring into the bottom half of the socket body. Using manual, vacuum-assisted, or magnetically-assisted tools load the top plunger into the top half of the socket body. (Magnetically assisted loading can be done if the top plunger is made of steel.) Put the two sections of the socket body together and clamp or otherwise hold them together. An alternative assembly process using a one-piece socket body contemplates loading the components into the cavity, and securing the Pariposer fabric (which may be held in a frame) to the bottom of the socket body to retain the pins from falling out. Alternatively, the spring-pin can be preassembled before it is placed into the socket body.

When the socket body is mounted on the PCB, the bottom plunger will push up against the spring and there will be enough pre-load to avoid movement (chattering) of the spring pin.

Only the top plunger moves, but there is a substantial amount of plunger travel relative to the overall length of the spring pin. Over-travel is prevented by a series of hard stops: “turtle-heading” of the top plunger into the machined block; compression spring reaches solid height; two plungers making contact with each other.

The signal path is down the center of the pin, through the shaft of the top plunger and then the annular barrel of the bottom plunger. It is not diverted to the spring or the skin of a traditional barrel. This path minimizes contact resistance and induction. Plating of the inside of the barrel of the lower plunger facilitates a low resistance and high bandwidth.

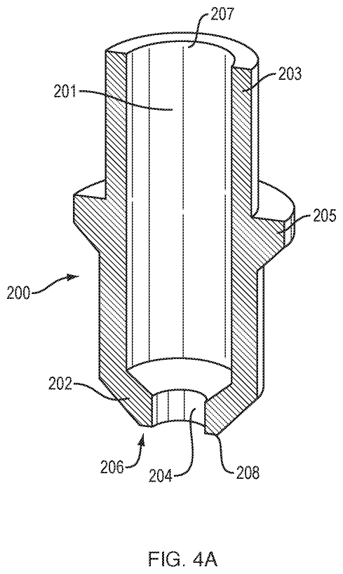

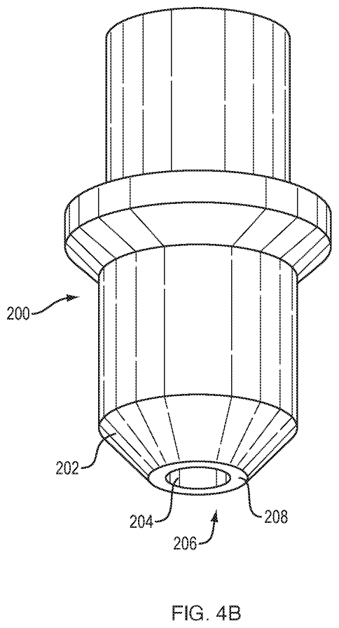

FIG. 4A is a cross-sectional view of an exemplary bottom plunger 200 for the spring pin. FIG. 4B is a perspective view of bottom plunger 200. Plunger 200 has annular wall or barrel 203 that defines hollow interior 201 with top opening 207. Intermediate flange 205 is used to retain the plunger in the cavity of the socket body. Bottom tip 202 is preferably conical, as shown. Bleed hole 204 is formed at the bottom end 206 of bottom tip 202. Preferably but not necessarily the bottom end 206 forms the narrow end of a truncated cone as shown in FIG. 4B, leaving flat lowest annular surface 208 that, as described above, provides a larger pad contact area than does the single contact geometry of a spherical tip. Also as can be seen, preferably there are no burrs or other protrusions around hole 204 or surface 208 that might damage a pad against which end 206 is contacted.

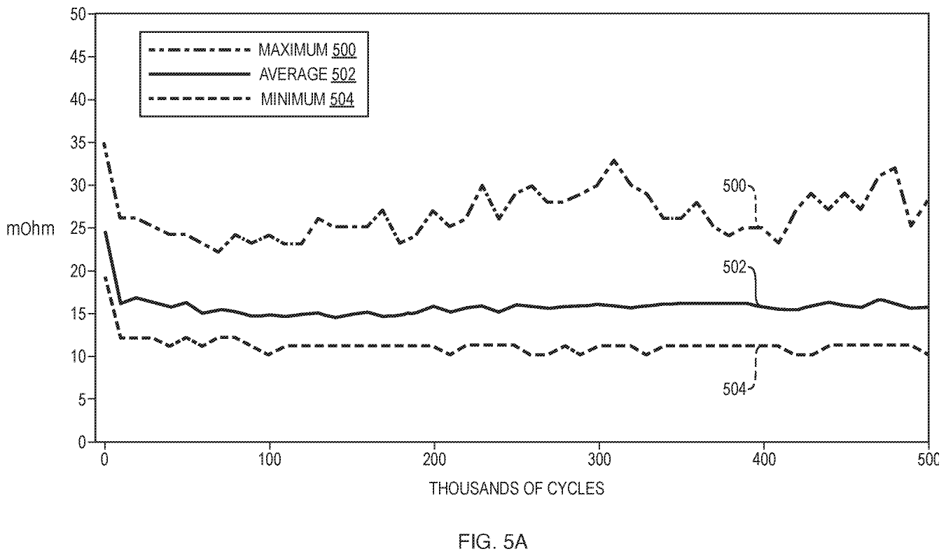

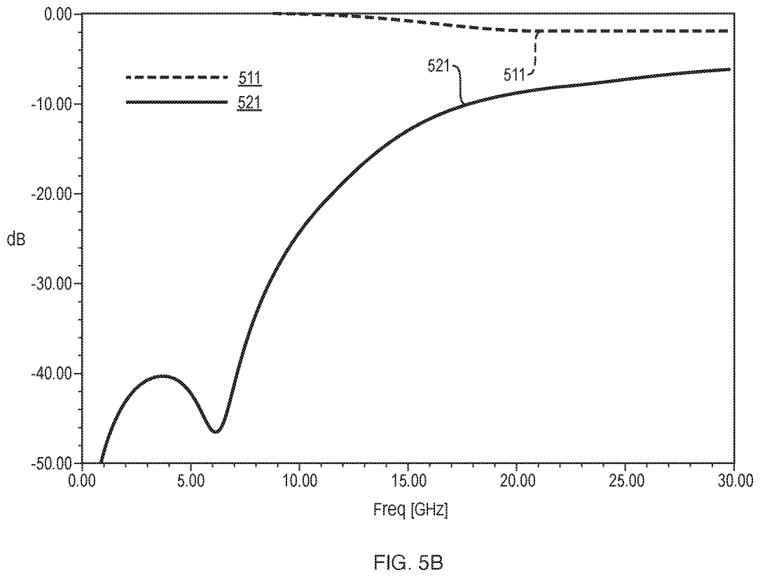

In a particular example of a spring pin such as shown in FIG. 1, the top element is made of hardened BeCu and nickel/gold plated, the bottom element is machined from solid bronze and nickel/gold plated on the inside of the barrel using the bleed hole in the bottom tip, and the spring is stainless steel. This pin has an average contact resistance of less than 30 mOhms, a current rating (ISMI Test) of 8.0 A, a −1 dB insertion Loss (S21) at 16.55 GHz, a −10 dB return loss (S11) at 17.60 GHz, a self-inductance of 0.85 nH, and a capacitance of 0.22 pF. FIG. 5A illustrates maximum, minimum, and average contact resistance (CRES) vs. Durability (thousands of cycles) for this spring pin. FIG. 5B illustrates the S11 and S21 electrical characteristics of the spring (dB v. frequency (GHz)). The solid walls and tip lead to more metal in cross-section, which helps to increase the CRES and the current rating. The tighter tolerance in the moving parts (in part due to the internal plating of the lower barrel after it has been machined from a solid rod) helps achieve the higher current rating. This spring pin has a much lower CRES, higher current rating, lower inductance, and greater bandwidth as compared to a spring pin wherein the lower barrel material is first plated, then stamped, and then rolled into a point.

A number of implementations have been described. Nevertheless, it will be understood that additional modifications may be made without departing from the scope of the inventive concepts described herein, and, accordingly, other examples are within the scope of the following claims.

What is claimed is:

1. A spring pin-based electrical interconnect system, comprising:
a non-conductive socket body;
a spring pin located in part in the socket body and defining two ends;
an anisotropically-conductive elastomeric sheet with first and second opposed surfaces, wherein the first surface is in contact with a first end of the spring pin; and
a PCB in contact with the second surface of the elastomeric sheet.

2. The system of claim 1, wherein the spring pin comprises a top plunger and a bottom plunger and an exterior spring.

3. The system of claim 2, wherein the socket body defines a cavity in which the spring pin is at least in part located.

4. The system of claim 3, wherein the top plunger and the bottom plunger each comprise a flange located in the socket body cavity.

5. The system of claim 3, wherein the top plunger comprises a flange located in the socket body cavity, and the bottom plunger comprises a flange that sits on the elastomeric sheet.

6. The system of claim 1, wherein the elastomeric sheet is configured to facilitate electrical connection between the spring pin and an electrical contact on the PCB.

7. A spring pin, comprising:
a top plunger element defining an electrical contact at one end, and a plunger at an opposed end;
a bottom barrel element that defines a cavity with an open top, wherein the plunger of the top plunger element is located and able to move up and down within the cavity, and a bottom tip with a through-hole that communicates with the cavity; and
a spring located outside of the top and bottom elements, the spring configured to produce a force that moves the plunger of the top element up within the cavity.

8. The spring pin of claim 7, further comprising a chamfer in the bottom tip.

9. The spring pin of claim 7, wherein the bottom tip is conical.

10. The spring pin of claim 9, wherein the bottom tip has a flat bottom.

11. The spring pin of claim 10, wherein the through-hole is in the flat bottom.

12. The spring pin of claim 9, wherein the bottom of the tip is annular.

13. The spring pin of claim 7, wherein the bottom element is unitary.

14. The spring pin of claim 13, wherein the bottom of the tip is closed except for the through-hole.

15. The spring pin of claim 7, wherein the top plunger further defines a flange between the ends.
